(19) United States
(12) Patent Application Publication
(10) Pub. No.: US 2009/0219678 A1
(43) Pub. Date: Sep. 3, 2009

(54) DISPLAY DEVICE

(75) Inventors: Hong-Cheng Hsiao, Tao Yuan Shien (TW); Ying-Hua Huang, Tao Yuan Shien (TW); Chin-Chang Lin, Tao Yuan Shien (TW)

Correspondence Address: QUINTERO LAW OFFICE, PC, 2210 MAIN STREET, SUITE 200, SANTA MONICA, CA, 90405, US

(73) Assignee: TECHVIEW INTERNATIONAL TECHNOLOGY INC., TAO YUAN SHIEN (TW)

(21) Appl. No.: 12/396,162

(22) Filed: Mar. 2, 2009

(30) Foreign Application Priority Data
Mar. 3, 2008 (TW) TW097107313

(51) Int. Cl. H05K 5/02

(52) U.S. Cl. 361/679.21

(57) ABSTRACT

A display device is provided, including a housing, a display panel, a shield, and an elastic member. The housing has a first frame and a second frame. The display panel, disposed in the housing, abuts the first frame. The shield, disposed in the housing, abuts the second frame. The elastic member, disposed between the display panel and the shield, includes a plurality of supporting portions, at least one abutting portion and an elastic portion extended from the abutting portion.

### CROSS REFERENCE TO RELATED APPLICATIONS

This Application claims priority of Taiwan Patent Application No. 97107313, filed on Mar. 3, 2008, the entirety of which is incorporated by reference herein.

### BACKGROUND OF THE INVENTION

1. Field of the Invention

The invention relates to a display device, and in particular, to a display device having the ability to receive display panels with different thicknesses, without drastically and inconveniently changing the original arranged structure.

2. Description of the Related Art

A conventional display device comprises an upper casing, a lower casing, a display panel and a shield. The shield is directly disposed on the display panel, and is fixed between the upper casing and the lower casing along with the display panel.

As technology advances, the display panel is becoming thinner and thinner. When the thickness of the display panel decreases, a gap is formed between the display panel and the shield. If no corresponding design or arrangement is made to fill up the gap therebetween, the interior components of the display device will not be appropriately fixed, thus resulting in a less-stable structure. Alternatively, a new casing may be fabricated to suit the new display panel, but manufacturing costs would accordingly increase.

### BRIEF SUMMARY OF THE INVENTION

The invention provides a display device. The display device comprises a housing, a display panel, a shield, and an elastic member. The housing has a first frame and a second frame. The display panel, disposed in the housing, abuts the first frame. The shield, disposed in the housing, abuts the second frame. The elastic member, disposed between the display panel and the shield, comprises a plurality of supporting portions, at least one abutting portion and an elastic portion extended from the abutting portion.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1A is an exploded view of a display device of the invention;

FIG. 1B is a partially exploded view of a portion A of the display device in FIG. 1A;

FIG. 2 is a schematic view of an elastic member of the invention; and

FIG. 3 is a schematic view of the elastic member and the shield of the invention.

### DETAILED DESCRIPTION OF THE INVENTION

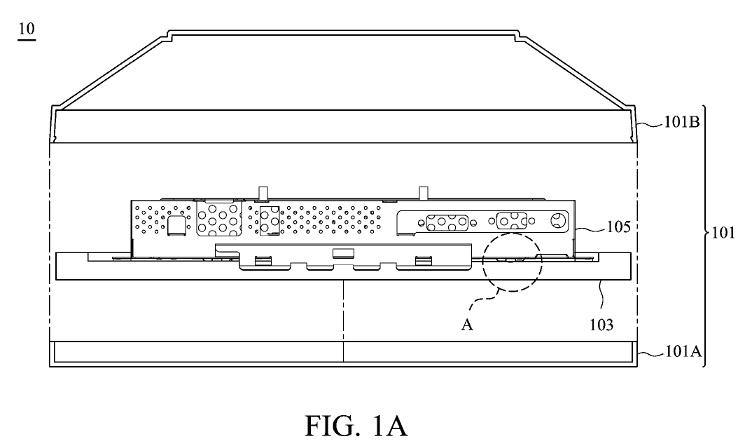

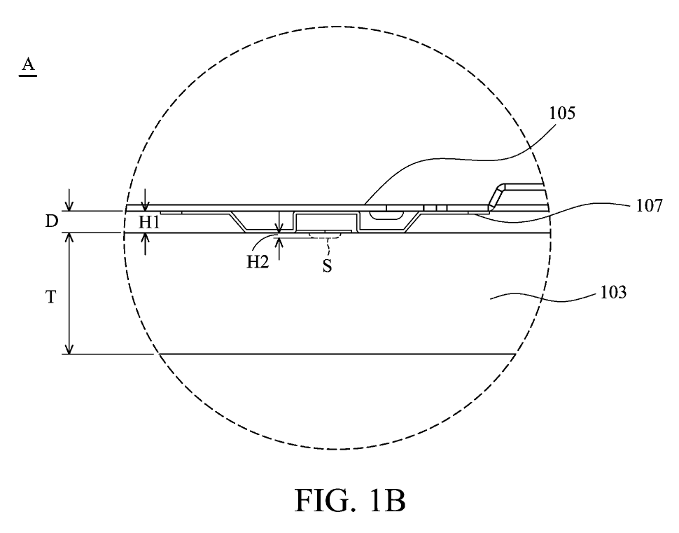

FIG. 1A depicts an exploded view of a display device of the invention, and FIG. 1B depicts a partially exploded view of a portion A of the display device in FIG. 1A. The display device 10 comprises a housing 101, a display panel 103, a shield 105 and a plurality of elastic members 107, wherein the housing 101 comprises a first frame 101A and a second frame 101B.

The display panel 103, disposed in the housing 101, abuts the first frame 101A. The shield 105, also disposed in the housing 101, abuts the second frame 101B. A distance D is formed between the display panel 103 and the shield 105.

In other words, in the embodiment, the display panel 103 is a new and improved flat panel comprising a thickness T (as shown in FIG. 1B). Because the thickness T of the display panel 103 is relatively thin, the distance D is formed between the display panel 103 and the shield 105. By disposition of the elastic members 107 between the display panel 103 and the shield 105 to fill up the gap formed by the distance D, the overall structure is thus enhanced.

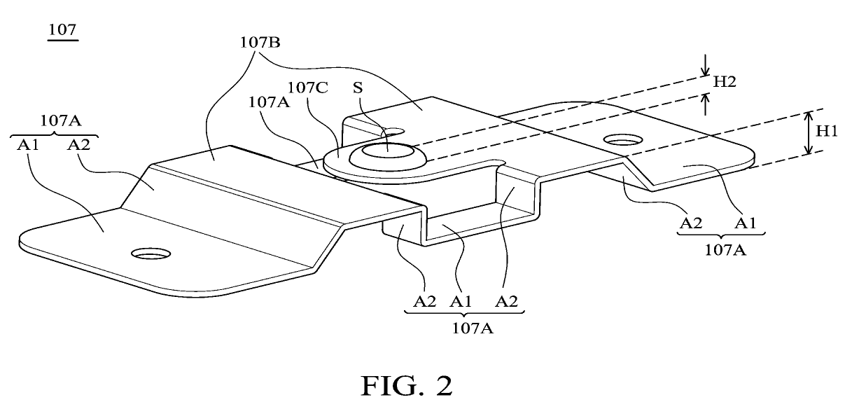

FIG. 2 depicts a schematic view of the elastic member of the invention. Referring to FIG. 1B and FIG. 2, each elastic member 107 comprises four supporting portions 107A, two abutting portions 107B and an elastic portion 107C. Besides, the supporting portions 107A, the abutting portions 107B and the elastic portion 107C are integrally formed as a single piece by metal. Each supporting portion 107A comprises a connecting portion and one or more than one supporting strips. Four supporting portions 107A alternately connect with two abutting portions 107B. The elastic portion 107C is horizontally extended from one of the abutting portions 107B to form a plate with a convex S disposed thereon.

Referring to FIG. 1B again, the supporting portion 107A of the elastic member 107 comprises a first height H1, and the convex S on the elastic portion 107C comprises a second height H2. The first height H1 equals to the distance D, and the first height H1 plus the second height H2 is substantially greater than the distance D.

Additionally, under the circumstance where the interior space of the housing 101 is fixed, the sum of the thickness T of the display panel 103 and the distance D of the shield 105 is also fixed. When the thickness T of the display panel 103 changes, the distance D accordingly changes. In other words, when the thickness T of the display panel 103 increases, the distance D relatively decreases. The first height Hi of the supporting portion 107A also accordingly decreases, and vice versa.

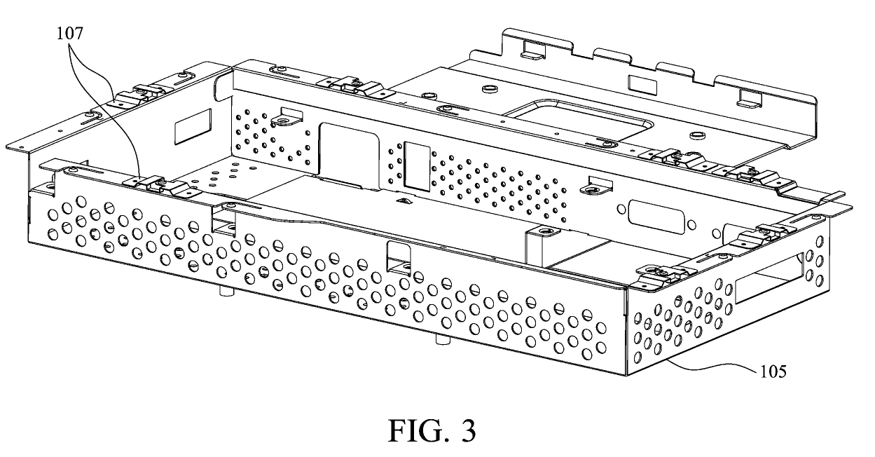

FIG. 3 depicts a schematic view of the elastic member and the shield of the invention. Referring to FIG. 1B and FIG. 3, a plurality of elastic members 107 is disposed on the periphery of the shield 105 by the supporting portions 107A (as shown in FIG. 3). The abutting portions 107B and the convex S abut the display panel, respectively. Because the first height H1 of the supporting portions 107 equals to the distance D between the display panel 103 and the shield 105, the elastic members 107, disposed between the display panel 103 and the shield 105, provide a supporting and connecting function, thus, avoiding displacement of the display panel 103 or the shield 105. Furthermore, the convex S comprises a second height H2. Additionally, when the abutting portions 107B abut the display panel 103, the convex S is pushed downward by the display panel 103. Therefore, an absolute shielding effect is generated as the elastic portions 107C provide elasticity to allow a tight contact between the convex S and the display panel 103.

The invention uses the disposition of the elastic members, so that the display device is able to be assembled with different types of display panels with different thicknesses. Accordingly, the main structure of the display device does not have to be redesigned, thus, saving costs, stabilizing the overall structure and improving shielding ability over conventional non-altered or non-redesigned display devices.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A display device, comprising:
a housing having a first frame and a second frame;
a display panel disposed in the housing and abutting the first frame;
a shield disposed in the housing and abutting the second frame; and
an elastic member disposed between the display panel and the shield, comprising:
a plurality of supporting portions;
at least one abutting portion; and
an elastic portion extended from the abutting portion.

2. The display device as claimed in claim 1, wherein the supporting portion is disposed on the shield.

3. The display device as claimed in claim 1, wherein the display device comprises three supporting portions and two abutting portions, and the supporting portions alternately connect with the abutting portions.

4. The display device as claimed in claim 1, wherein the abutting portion abuts the display panel.

5. The display device as claimed in claim 1, wherein the elastic portion comprises a convex.

6. The display device as claimed in claim 5, wherein the convex abuts the display panel.

7. The display device as claimed in claim 1, wherein the elastic portion abuts the display panel.

8. The display device as claimed in claim 1, wherein the supporting portions, the abutting portion and the elastic portion of the elastic member are integrally formed as a single piece.

9. The display device as claimed in claim 1, wherein a distance is formed between the display panel and the shield, and the supporting portions of the elastic member comprises a first height which is equal to the distance.

10. The display device as claimed in claim 9, wherein the display panel comprises a thickness, and the sum of the thickness and the distance is fixed, such that when the thickness is reduced, the distance is relatively increased.

11. The display device as claimed in claim 9, wherein the elastic portion comprises a convex having a second height, and the first height plus the second height is substantially greater than the distance.

12. The display device as claimed in claim 1, wherein the elastic member comprises metal.
